(19) United States
(12) Patent Application Publication
(10) Pub. No.: US 2012/0122288 A1
(43) Pub. Date: May 17, 2012

(54) METHOD OF FABRICATING A SILICIDE LAYER

(76) Inventors: Chao-Ching Hsieh, Tainan City (TW); Nien-Ting Ho, Tainan City (TW)

(21) Appl. No.: 12/944,738

(22) Filed: Nov. 12, 2010

(51) Int. Cl. H01L 21/336

(52) U.S. Cl. 438/308; 438/664; 257/E21.409

(57) ABSTRACT

During a salicide process, and before a second thermal treatment is performed to a silicide layer of a semiconductor substrate, a thermal conductive layer is formed to cover the silicide layer. The heat provided by the second thermal treatment can be conducted to the silicide layer uniformly through the thermal conductive layer. The thermal conductive layer can be a CESL layer, TiN, or amorphous carbon. Based on different process requirements, the thermal conductive layer can be removed optionally after the second thermal treatment is finished.

### BACKGROUND OF THE INVENTION

1. Field of the Invention

The present invention relates to a method of fabricating a silicide layer, and more particularly, to a method of fabricating a semiconductor device with a silicide layer.

2. Description of the Prior Art

As integration of elements in integrated circuits (IC) increases, line widths and geometries for semiconductor devices are reduced. Accordingly, resistance of a gate and source/drain regions of a MOS transistor made by conventional techniques is relatively high. To reduce resistance, a metal silicide layer is formed on the gate and the source/drain regions by a self-aligned silicide (salicide) process. Nickel silicide (NiSi) is commonly used as a salicide material.

Because the NiSi layer is formed by two thermal treatments, however, the temperature employed in the latter treatment is generally higher. Temperatures over about 500 C. usually cause silicide agglomeration. As a result, the NiSi layer is formed discontinuously and resistance is thereby increased which affects the electric properties.

Therefore, there is still a need for a novel method to prevent the silicide layer from agglomeration during the thermal treatments.

### SUMMARY OF THE INVENTION

An objective of the present invention is to provide a method of fabricating a MOS transistor in which agglomeration of the silicide layer can be reduced.

The method of fabricating a silicide layer according to an embodiment of the present invention includes the following steps.

First, a substrate having a silicon-containing region is provided. Then, a metal layer is formed on the silicon-containing region. After that, a first thermal treatment is performed to the metal layer and the silicon-containing region to forma silicide layer on the silicon-containing region. Later, an etching stop layer (CESL) is formed on the substrate and the silicide layer. Finally, after the etching stop layer is formed, a second thermal treatment is performed to the silicide layer.

The method of fabricating a silicide layer according to another embodiment of the present invention includes the following steps.

A semiconductor substrate having a silicon-containing region is provided. Later, a metal layer is formed on the silicon-containing region. Subsequently, a first thermal treatment is performed to the metal layer and silicon-containing region to form a silicide layer on the silicon-containing region. After that, a thermal conductive layer is formed on the substrate and the silicide layer. After the thermal conductive layer is formed, a second thermal treatment is performed to the silicide layer. Next, the thermal conductive layer is removed. Finally, an etching stop layer is formed on the substrate and the silicide layer.

The CESL or the thermal conductive layer can conduct the heat uniformly, therefore, the silicide layer underneath can be heated evenly. As a result, the agglomeration of the silicide layer can be prevented.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1 to 4 are schematic cross-sectional views illustrating a method of fabricating a silicide layer according to a first embodiment of the present invention;

FIGS. 5 to 8 are schematic cross-sectional views illustrating a method of fabricating a silicide layer according to a second embodiment of the present invention.

FIG. 9 depicts a schematic cross-sectional view illustrating a MOS transistor has low parasitic resistance and low junction leakage.

FIG. 10 depicts a flow chart of a method of fabricating a MOS transistor has low parasitic resistance and low junction leakage.

FIG. 11 depicts a silicide layer disposed on a gate of a MOS transistor.

### DETAILED DESCRIPTION

FIGS. 1 to 4 are schematic cross-sectional views illustrating a method of fabricating a silicide layer according to a first embodiment of the present invention.

As shown in FIG. 1, a substrate 10 is provided. The substrate 10 can be a silicon-containing substrate such as a single-crystalline substrate, a polysilicon substrate or a silicon-on-insulator substrate. A MOS transistor 12 is disposed on the substrate 10. The MOS transistor 12 includes a gate structure 14, and a source/drain region 16 in the substrate 10 at two sides of the gate structure 14. The gate structure 14 can include a gate 18, a gate dielectric layer 20 disposed between the gate 18 and the substrate 10, a spacer 22 disposed on the gate 18, and a cap layer 24 disposed on the top surface of the gate 18. Based on different product requirements, the gate may be a polysilicon gate or a metal gate.

Then, a salicide block layer (not shown) is formed on the substrate 10 and the source/drain region 16 is exposed through the salicide block layer. In FIG. 1, the entire MOS transistor 12 is exposed through the salicide block layer. After that, a metal layer 26 is formed on the substrate 10, the gate structure 14, the source/drain region 16 and the salicide block layer. The metal layer 26 can be Ni, Ti, Co or other metals.

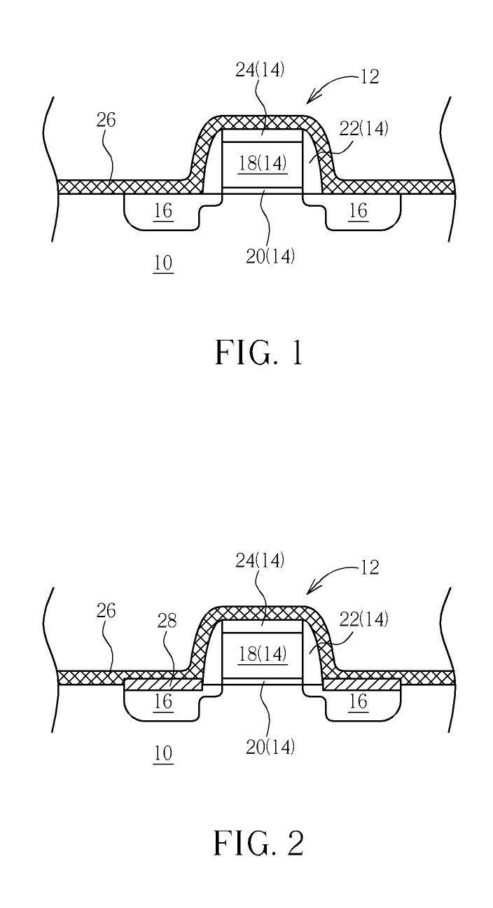

As shown in FIG. 2, a first thermal treatment is performed to the metal layer 26 and the source/drain region 16. The first thermal treatment can be an anneal process such as a rapid thermal process preferably performed at 220° C. to 350° C. After the first thermal treatment, a silicide layer 28 is formed at the source/drain region 16. According to a preferred embodiment of the present invention, the silicide layer 28 is preferably a NiSi layer.

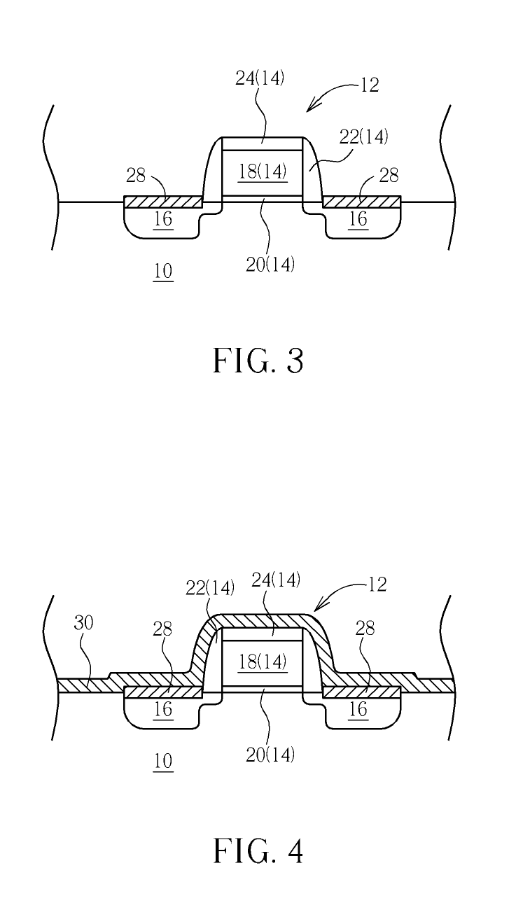

As shown in FIG. 3, the metal layer 26 which is not reacted is removed, and the silicide layer 28 remains at the source/drain region 16. The salicide block layer can be removed optionally.

As shown in FIG. 4, an etching stop layer (CESL) 30 is formed on the gate structure 14, the silicide layer 28 and the substrate 10. The CESL 30 can be silicon nitride or silicon oxide. Later, a second thermal treatment is performed to the silicide layer 28. The second thermal treatment may be a millisecond anneal (MSA) performed preferably at 700° C. to 1000° C. At this point, the method of fabricating a silicide layer of the first embodiment is completed.

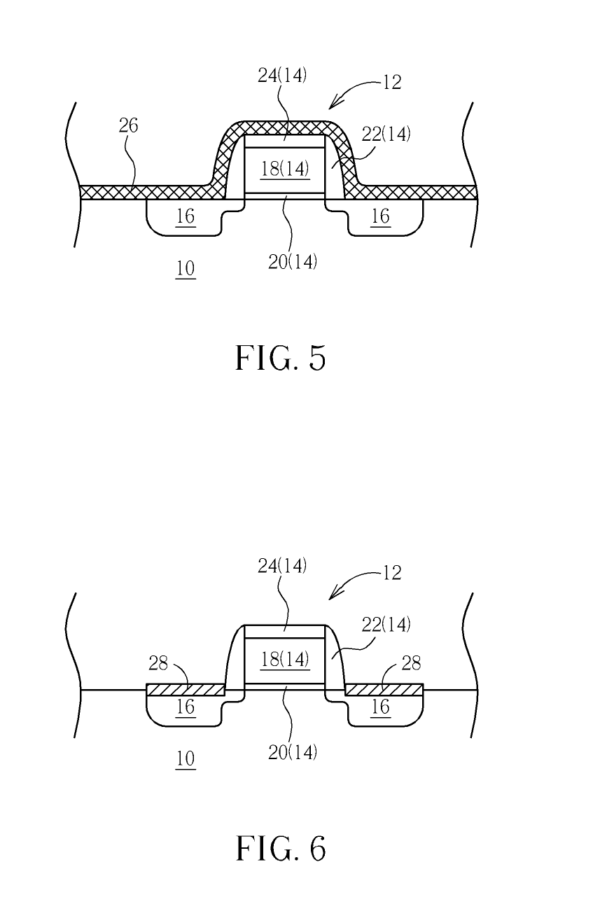

FIGS. 5 to 8 are schematic cross-sectional views illustrating a method of fabricating a silicide layer according to the second embodiment of the present invention.

The steps in FIG. 5 through FIG. 6 are the same as the steps described in FIG. 1 through FIG. 3. For the sake of brevity, the steps in FIG. 5 to FIG. 6 will only be described briefly. In the second embodiment, like numbered numerals designate the same parts, regions or elements as that in the first embodiment.

As shown in FIG. 5, first, a substrate 10 is provided. The substrate 10 can be a silicon-containing substrate. A MOS transistor 12 is disposed on the substrate 10. The MOS transistor 12 includes a gate structure 14, and a source/drain region 16 in the substrate 10 at two sides of the gate structure 14. The gate structure 14 can include a gate 18, a gate dielectric layer 20 disposed between the gate 18 and the substrate 10, a spacer 22 disposed on the gate 18, and a cap layer 24 disposed on the top surface of the gate 18. The gate 18 may be a polysilicon gate or a metal gate.

Then, a salicide block layer (not shown) is formed on the substrate 10 and the source/drain region 16 is exposed through the salicide block layer. After that, a metal layer 26 is formed on the substrate 10, the gate structure 14, the source/drain region 16 and the salicide block layer.

As shown in FIG. 6, a first thermal treatment is performed to the metal layer 26 and the source/drain region 16. The first thermal treatment can be an anneal process preferably performed at 220° C. to 350° C. After the first thermal treatment, a silicide layer 28 is formed at the source/drain region 16.

Later, the metal layer 26 which is not reacted is removed, and the silicide layer 28 remains at the source/drain region 16. The salicide block layer can be removed optionally.

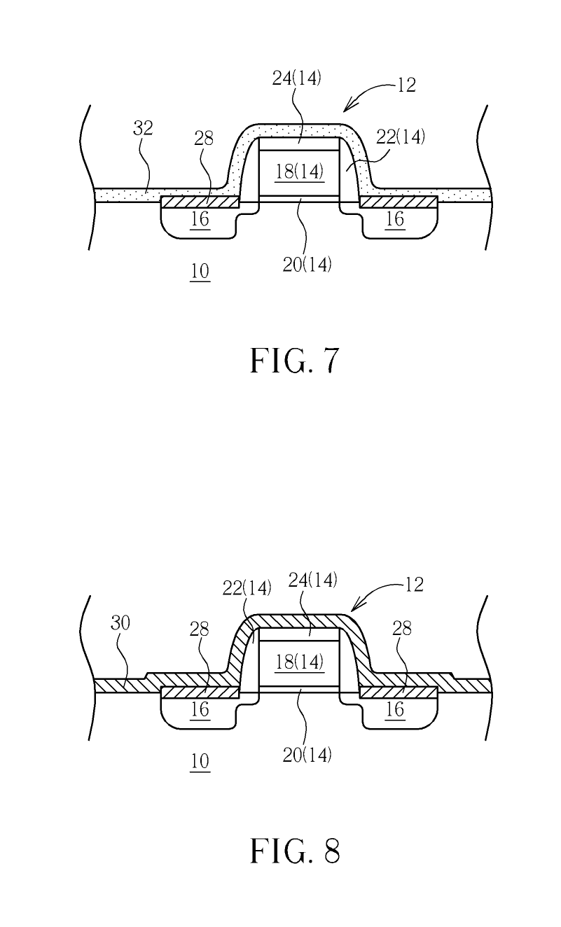

As shown in FIG. 7, a thermal conductive layer 32 is formed on the gate structure 14, the silicide layer 28 and the substrate 10. The thermal conductive layer 32 maybe TiN, amorphous carbon or other thermal conductive materials which can spread the heat uniformly.

Later, a second thermal treatment is performed to the silicide layer 28. The second thermal treatment may be a millisecond anneal (MSA) performed preferably at 700° C. to 1000° C.

As shown in FIG. 8, the thermal conductive layer is removed. After that, a CESL 30 is formed on the gate structure 14, the source/drain region 16 and the salicide layer 28. The CESL 30 can be silicon nitride or silicon oxide. At this point, the method of fabricating a silicide layer of the second embodiment is formed completed.

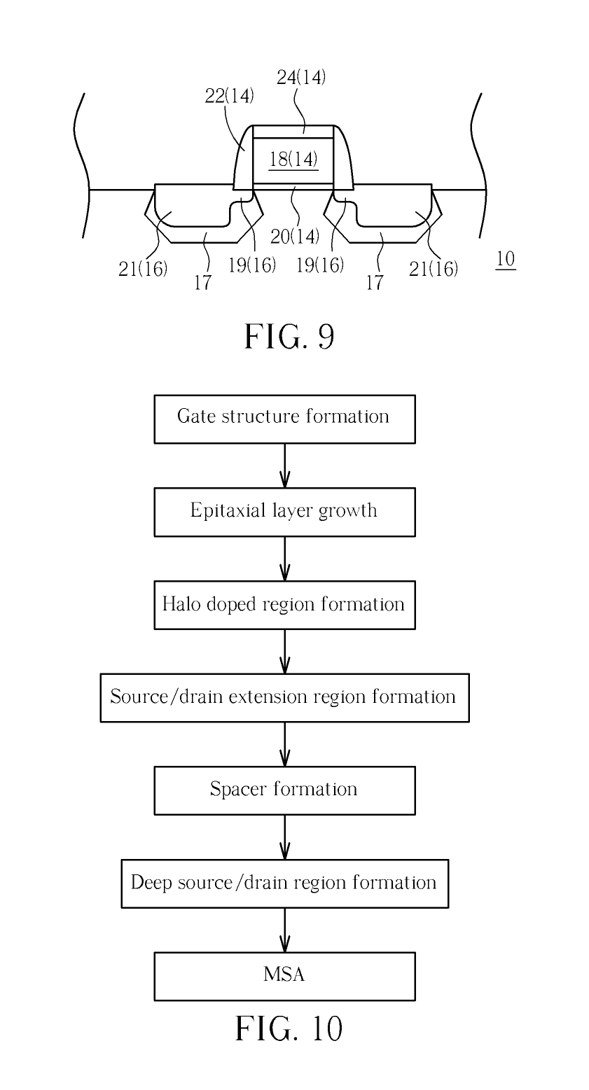

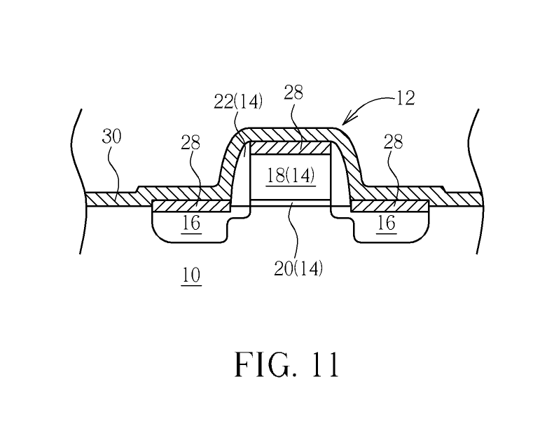

FIG. 9 depicts a schematic cross-sectional view illustrating a MOS transistor has low parasitic resistance and low junction leakage. FIG. 10 depicts a flow chart of a method of fabricating a MOS transistor has low parasitic resistance and low junction leakage. According to another preferred embodiment, the MOS transistor 12 may be made to have low parasitic resistance and low junction leakage by the steps as follows.

Please refer to both FIG. 9 and FIG. 10, first, the gate structure 14 is formed on the substrate 10. Then, an epitaxial silicon layer 17 is formed beside the gate structure 14. After that, a halo implantation process is performed to form a halo doped region (not shown) at a side of the gate structure 14. Later, a source/drain extension region 19 is formed in the epitaxial silicon layer 17 by taking the gate structure 14 as a mask. The source/drain extension region 19 is formed by a cluster ion implantation. For example, the source/drain extension region 19 is formed by implanting B₁₈H₂₂ into the epitaxial silicon layer 17. Later, the spacer 22 is formed at two sides of the gate structure 14. Subsequently, a deep source/drain region 21 is formed in the epitaxial silicon layer 17. Next, a millisecond anneal is performed to diffuse the source/drain extension region 19 and the deep source/drain region 21. The source/drain extension region 19 and the deep source/drain region 21 form the source/drain region 16. Because the source/drain extension region 19 is formed in the epitaxial silicon layer 17, the source/drain extension region 19 is raised.

The combination steps such as the millisecond anneal, and implanting B₁₈H₂₂ into the epitaxial silicon layer are effective to reduce parasitic resistance and junction leakage of the MOS transistor 12. The raised source/drain extension region 19 is capable of suppress parasitic resistance. The steps including the millisecond anneal, implanting B₁₈H₂₂ into the epitaxial silicon layer and raising the source/drain extension region 19 can be performed individually and optionally. Therefore, the MOS transistor 12 in FIG. 1 and FIG. 7 can be replaced by the MOS transistor 12 made by the process shown in FIG. 10.

The method of the present invention may be utilized to make a silicide layer applied to any silicon-containing region, for example, to a source/drain region of a MOS transistor, or a gate of a MOS transistor. FIG. 11 shows the example of the silicide layer disposed on a gate of a MOS transistor, wherein like numbered numerals designate the same parts, regions or elements as that in the first embodiment. As shown in FIG. 11, the MOS transistor 12 has a silicide layer 28 disposed on the gate 18.

The millisecond anneal performed during the second thermal treatment can heat the silicide rapidly. Therefore, after the second thermal treatment, the silicide layer will form stresses inside, and the performance of the drive current (Iₒₙ) and the off state leakage current (I_{off}) can be improved. It is note-worthy that the CESL or the thermal conductive layer can spread the heat from the millisecond anneal evenly. Therefore, during the second thermal treatment, the silicide layer under the CESL or the thermal conductive layer can be heated uniformly, and the agglomeration of the silicide layer can be prevented.

Those skilled in the art will readily observe that numerous modifications and alterations of the device and method may be made while retaining the teachings of the invention.

What is claimed is:

1. A method of fabricating a silicide layer, comprising:
providing a substrate having a silicon-containing region;
forming a metal layer on the silicon-containing region;
performing a first thermal treatment to the metal layer and the silicon-containing region to form a silicide layer on the silicon-containing region;
forming an etching stop layer on the substrate and the silicide layer; and
after forming the etching stop layer, performing a second thermal treatment to the silicide layer.

2. The method of fabricating a silicide layer of claim 1, wherein the first thermal treatment comprises an anneal process.

3. The method of fabricating a silicide layer of claim 2, wherein the anneal process is performed at 220° C. to 350° C.

4. The method of fabricating a silicide layer of claim 1, wherein the second thermal treatment comprises a millisecond anneal.

5. The method of fabricating a silicide layer of claim 4, wherein the millisecond anneal is performed at 700° C. to 1000° C.

6. The method of fabricating a silicide layer of claim 1, further comprising, after the first thermal treatment, removing the metal layer which is not reacted.

7. The method of fabricating a silicide layer of claim 1, wherein the etching stop layer comprises silicon oxide or silicon nitride.

8. The method of fabricating a silicide layer of claim 1, wherein the silicon-containing region comprises a source/drain region or a gate.

9. The method of fabricating a silicide layer of claim 1, further comprising:
before forming a metal layer on the silicon-containing region, forming an epitaxial layer in the silicon-containing region.

10. The method of fabricating a silicide layer of claim 9, further comprising:
performing a cluster ion implantation to the epitaxial layer.

11. The method of fabricating a silicide layer of claim 10, further comprising:
after performing a cluster ion implantation, annealing the substrate.

12. A method of fabricating a silicide layer, comprising:
providing a semiconductor substrate having a silicon-containing region;
forming a metal layer on the silicon-containing region;
performing a first thermal treatment to the metal layer and the silicon-containing region to form a silicide layer on the silicon-containing region;
forming a thermal conductive layer on the substrate, and the silicide layer;
after forming the thermal conductive layer, performing a second thermal treatment to the silicide layer;
removing the thermal conductive layer; and
forming an etching stop layer on the substrate, and the silicide layer.

13. The method of fabricating a silicide layer of claim 12, wherein the first thermal treatment comprises an anneal process.

14. The method of fabricating a silicide layer of claim 13, wherein the anneal process is performed at 250° C. to 350° C.

15. The method of fabricating a silicide layer of claim 12, wherein the second thermal treatment comprises a millisecond anneal.

16. The method of fabricating a silicide layer of claim 15, wherein the millisecond anneal is performed at 700° C. to 1000° C.

17. The method of fabricating a silicide layer of claim 12, wherein the thermal conductive layer comprises TiN or amorphous carbon.

18. The method of fabricating a silicide layer of claim 12, wherein the etching stop layer is formed after the thermal conductive layer is removed.

19. The method of fabricating a silicide layer of claim 12, wherein the etching stop layer comprises silicon oxide or silicon nitride.

20. The method of fabricating a silicide layer of claim 12, further comprising after the first thermal treatment, removing the metal layer which is not reacted.

21. The method of fabricating a silicide layer of claim 12, further comprising:
before forming a metal layer on the silicon-containing region, forming an epitaxial layer in the silicon-containing region.

22. The method of fabricating a silicide layer of claim 21, further comprising:
performing a cluster ion implantation to the epitaxial layer.

23. The method of fabricating a silicide layer of claim 22, further comprising:
after performing a cluster ion implantation, annealing the substrate.
